(19) United States
(12) Patent Application Publication
(10) Pub. No.: US 2010/0148291 A1
(43) Pub. Date: Jun. 17, 2010

(54) ULTRAVIOLET LIGHT FILTER LAYER IN IMAGE SENSORS

(76) Inventors: Cristian A. Tivarus, Rochester, NY (US); John P. McCarten, Penfield, NY (US); Joseph R. Summa, Hilton, NY (US)

Correspondence Address: Pedro P. Hernandez;Panent Legal Staff, Eastman Kodak Company, 343 State Street, Rochester, NY, 14650-2201, US

(21) Appl. No.: 12/612,707

(22) Filed: Nov. 5, 2009

Related U.S. Application Data
(60) Provisional application No. 61/122,428, filed on Dec. 15, 2008.

(51) Int. Cl. H01L 31/0232; H01L 31/18

(52) U.S. Cl. 257/432; 438/70; 257/E31.127; 257/E31.121; 257/E21.598

(57) ABSTRACT

An image sensor includes one or more ultraviolet (UV) light filter layers disposed between an insulating layer and a color filter array (CFA) layer. The one or more UV light filter layers reflect or absorb UV light while transmitting visible light.

### CROSS-REFERENCE TO RELATED APPLICATION

This application claims the benefit of U.S. Provisional Application No. 61/122,428 filed on Dec. 15, 2008, which is incorporated herein by reference.

### TECHNICAL FIELD

The present invention relates generally to image sensors for use in digital cameras and other types of image capture devices, and more particularly to image sensors having one or more ultraviolet light filter layers formed on the image sensor prior to the formation of the color filter array.

### BACKGROUND

A typical electronic image sensor includes a number of light sensitive picture elements (“pixels”) arranged in a two-dimensional array in a sensor layer. Such an image sensor may be configured to produce a color image by forming a color filter array (CFA) over the pixels. One commonly used type of CFA pattern is the Bayer pattern, disclosed in U.S. Pat. No. 3,971,065, entitled “Color Imaging Array,” which is incorporated by reference herein. The Bayer CFA pattern provides each pixel with color photoresponse exhibiting a predominant sensitivity to one of three designated portions of the visible spectrum. The three designated portions may be, for example, red, green and blue, or cyan, magenta and yellow. A given CFA pattern is generally characterized by a minimal repeating unit in the form of a subarray of contiguous pixels that acts as a basic building block for the pattern. Multiple copies of the minimal repeating unit are juxtaposed to form the complete pattern.

Typically, an image sensor is exposed to ultraviolet (UV) light when the CFA is deposited on the image sensor. UV light is known to induce charge in an immediately underlying insulating layer, as well as defect states at the interface between the insulating and sensor layers.

These interface states and the charge induced in the insulating layers increase the level of dark current and reduce the quantum efficiency of the back-illuminated imagers. Temperature annealing can be performed to reduce or eliminate these induced defects, but the low temperature requirements of the CFA layer limits the temperature at which the annealing can be performed, thereby reducing the beneficial effects of the annealing process.

### SUMMARY

An image sensor includes one or more ultraviolet (UV) light filter layers formed on one or more insulating layers. A color filter array (CFA) layer is then formed on the one or more UV light filter layers. The one or more UV light filter layers block UV light from striking the underlying layers. UV light filter layer or layers reflect or absorb UV light while transmitting visible light. By way of example only, the one or more UV filter layers are formed with a thin silicon layer deposited on the insulating layer or an unetched thin silicon layer if a back-illuminated image sensor is built on a SOI wafer, an ONONO dichroic stack, or an organic or inorganic dyed polymer in exemplary embodiments in accordance with the invention. The image sensor can be configured as a front-illuminated or back-illuminated image sensor.

### ADVANTAGEOUS EFFECT

The present invention includes the advantage of reducing or eliminating insulator charging and insulator-sensor interface states generation as a result of exposure to UV light. Reducing or eliminating these effects preserves the level of dark current and quantum efficiency of the image sensor.

### BRIEF DESCRIPTION OF THE DRAWINGS

Embodiments of the invention are better understood with reference to the following drawings. The elements of the drawings are not necessarily to scale relative to each other.

FIG. 1 is a simplified block diagram of an image capture device in an embodiment in accordance with the invention;

FIG. 2 is a simplified block diagram of image sensor 106 shown in FIG. 1 in an embodiment in accordance with the invention;

FIG. 3 is a flowchart of a method for fabricating an image sensor in an embodiment in accordance with the invention;

FIG. 4 is a graph depicting the silicon absorption coefficient for different wavelengths of light;

FIG. 5 is a cross section view of a front-illuminated image sensor fabricated pursuant to the method shown in FIG. 4 in an embodiment in accordance with the invention; and

FIG. 6 is a cross section view of a back-illuminated image sensor fabricated pursuant to the method shown in FIG. 4 in an embodiment in accordance with the invention.

### DETAILED DESCRIPTION

Throughout the specification and claims, the following terms take the meanings explicitly associated herein, unless the context clearly dictates otherwise. The meaning of “a,” “an,” and “the” includes plural reference, the meaning of “in” includes “in” and “on.” The term “connected” means either a direct electrical connection between the items connected or an indirect connection through one or more passive or active intermediary devices. The term “circuit” means either a single component or a multiplicity of components, either active or passive, that are connected together to provide a desired function. The term “signal” means at least one current, voltage, or data signal.

Additionally, directional terms such as “on”, “over”, “top”, “bottom”, are used with reference to the orientation of the Figure(s) being described. Because components of embodiments of the present invention can be positioned in a number of different orientations, the directional terminology is used for purposes of illustration only and is in no way limiting. When used in conjunction with layers of an image sensor wafer or corresponding image sensor, the directional terminology is intended to be construed broadly, and therefore should not be interpreted to preclude the presence of one or more intervening layers or other intervening image sensor features or elements. Thus, a given layer that is described herein as being formed on or formed over another layer may be separated from the latter layer by one or more additional layers.

And finally, the terms “wafer” and “substrate” are to be understood as a semiconductor-based material including, but not limited to, silicon, silicon-on-insulator (SOI) technology, silicon-on-sapphire (SOS) technology, doped and undoped semiconductors, epitaxial layers formed on a semiconductor substrate, and other semiconductor structures.

Referring to the drawings, like numbers indicate like parts throughout the views.

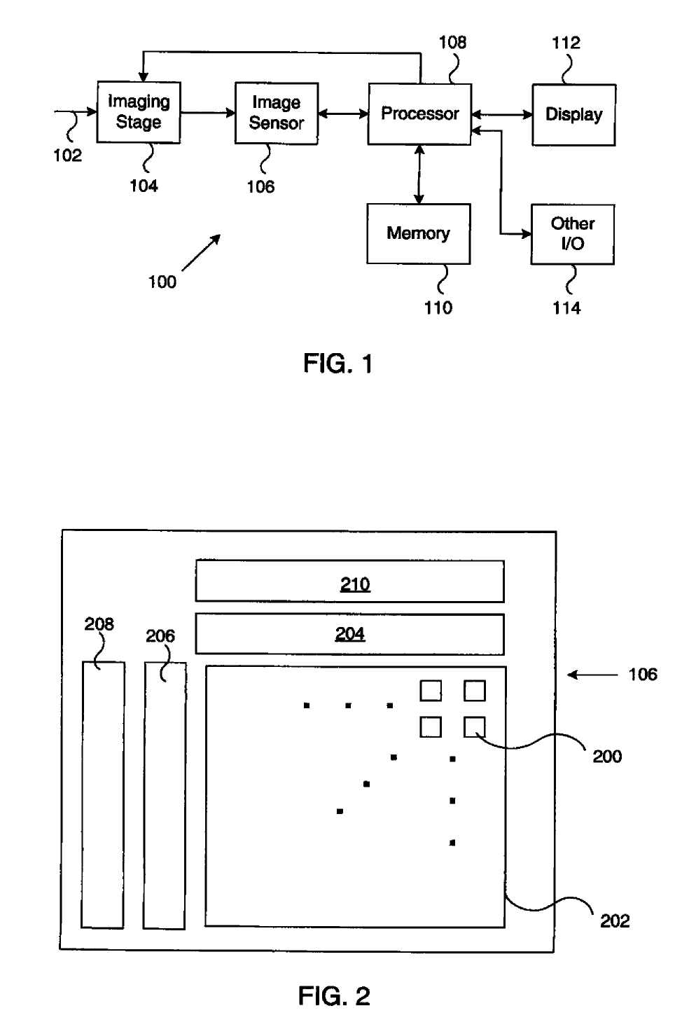

Referring now to FIG. 1, there is shown a simplified block diagram of an image capture device in an embodiment in accordance with the invention. Image capture device 100 is implemented as a digital camera in FIG. 1. Those skilled in the art will recognize that a digital camera is only one example of an image capture device that can utilize an image sensor incorporating the present invention. Other types of image capture devices, such as, for example, cell phone cameras and digital video camcorders, can be used with the present invention.

In digital camera 100, light 102 from a subject scene is input to an imaging stage 104. Imaging stage 104 can include conventional elements such as a lens, a neutral density filter, an iris and a shutter. Light 102 is focused by imaging stage 104 to form an image on image sensor 106. Image sensor 106 captures one or more images by converting the incident light into electrical signals. Digital camera 100 further includes processor 108, memory 110, display 112, and one or more additional input/output (I/O) elements 114. Although shown as separate elements in the embodiment of FIG. 1, imaging stage 104 may be integrated with image sensor 106, and possibly one or more additional elements of digital camera 100, to form a compact camera module.

Processor 108 may be implemented, for example, as a microprocessor, a central processing unit (CPU), an application-specific integrated circuit (ASIC), a digital signal processor (DSP), or other processing device, or combinations of multiple such devices. Various elements of imaging stage 104 and image sensor 106 may be controlled by timing signals or other signals supplied from processor 108.

Memory 110 may be configured as any type of memory, such as, for example, random access memory (RAM), read-only memory (ROM), Flash memory, disk-based memory, removable memory, or other types of storage elements, in any combination. A given image captured by image sensor 106 may be stored by processor 108 in memory 110 and presented on display 112. Display 112 is typically an active matrix color liquid crystal display (LCD), although other types of displays may be used. The additional I/O elements 114 may include, for example, various on-screen controls, buttons or other user interfaces, network interfaces, or memory card interfaces.

It is to be appreciated that the digital camera shown in FIG. 1 may comprise additional or alternative elements of a type known to those skilled in the art. Elements not specifically shown or described herein may be selected from those known in the art. As noted previously, the present invention may be implemented in a wide variety of image capture devices. Also, certain aspects of the embodiments described herein may be implemented at least in part in the form of software executed by one or more processing elements of an image capture device. Such software can be implemented in a straightforward manner given the teachings provided herein, as will be appreciated by those skilled in the art.

FIG. 2 is a simplified block diagram of image sensor 106 shown in FIG. 1 in an embodiment in accordance with the invention. Image sensor 106 includes a number of pixels 200 that are typically arranged in rows and columns to form an imaging area 202. Image sensor 106 further includes column decoder 204, row decoder 206, digital logic 208, and analog or digital output circuits 210. Image sensor 106 is implemented as a back or front-illuminated Complementary Metal Oxide Semiconductor (CMOS) image sensor in an embodiment in accordance with the invention. Thus, column decoder 204, row decoder 206, digital logic 208, and analog or digital output circuits 210 are implemented as standard CMOS electronic circuits that are electrically connected to imaging area 202.

Functionality associated with the sampling and readout of imaging area 202 and the processing of corresponding image data may be implemented at least in part in the form of software that is stored in memory 110 (see FIG. 1) and executed by processor 108. Portions of the sampling and readout circuitry may be arranged external to image sensor 106, or formed integrally with imaging area 202, for example, on a common integrated circuit with photodetectors and other elements of the imaging area. Those skilled in the art will recognize that other peripheral circuitry configurations or architectures can be implemented in other embodiments in accordance with the invention.

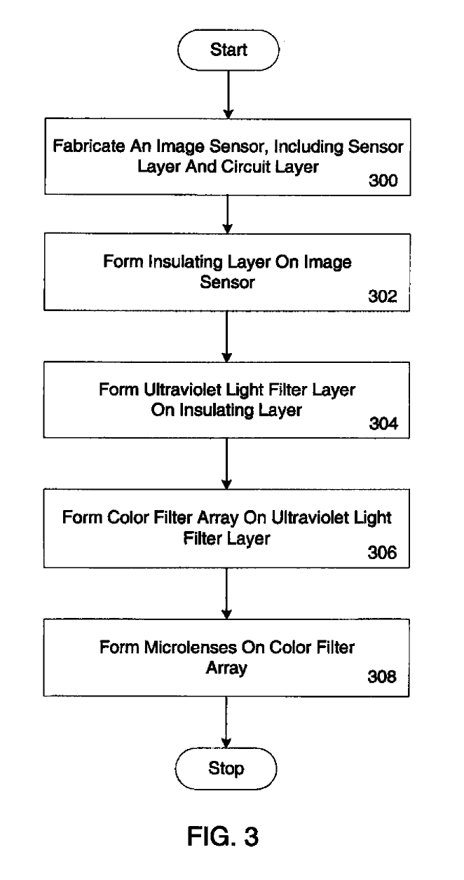

Referring now to FIG. 3, there is shown a flowchart of a method for fabricating an image sensor in an embodiment in accordance with the invention. Initially, as shown in block 300, an image sensor is fabricated, including the sensor layer and the circuit layer. The image sensor, including the sensor layer and the circuit layer, can be constructed using any known technique for fabricating an image sensor. The image sensor can be configured as a front-illuminated or back-illuminated image sensor.

The sensor layer includes a number of photodetectors or other photosensitive elements that are typically arranged in rows and columns to form an array. The circuit layer includes conductive interconnects formed in one or more insulating layers. Inter-Level-Dielectric (ILD) and Inter-Metal-Dielectric (IMD) layers are examples of the types of layers that may be included in the circuit layer.

An insulating layer is then formed on a surface of the image sensor, as shown in block 302. With a back-illuminated image sensor, the insulating layer is formed on the backside of the sensor layer. With a front-illuminated image sensor, the insulating layer is formed on the frontside of the circuit layer.

One or more ultraviolet (UV) light filter layers are then formed on the insulating layer (block 304). The one or more UV light filter layers block UV light from striking the underlying layers. The one or more UV light filter layers reflect or absorb the UV light while transmitting visible light. One example of a material that can be used to implement the one or more UV light filter layers is a thin silicon layer. The thin silicon layer can have a thickness in the tens of nanometers in one or more embodiments in accordance with the invention.

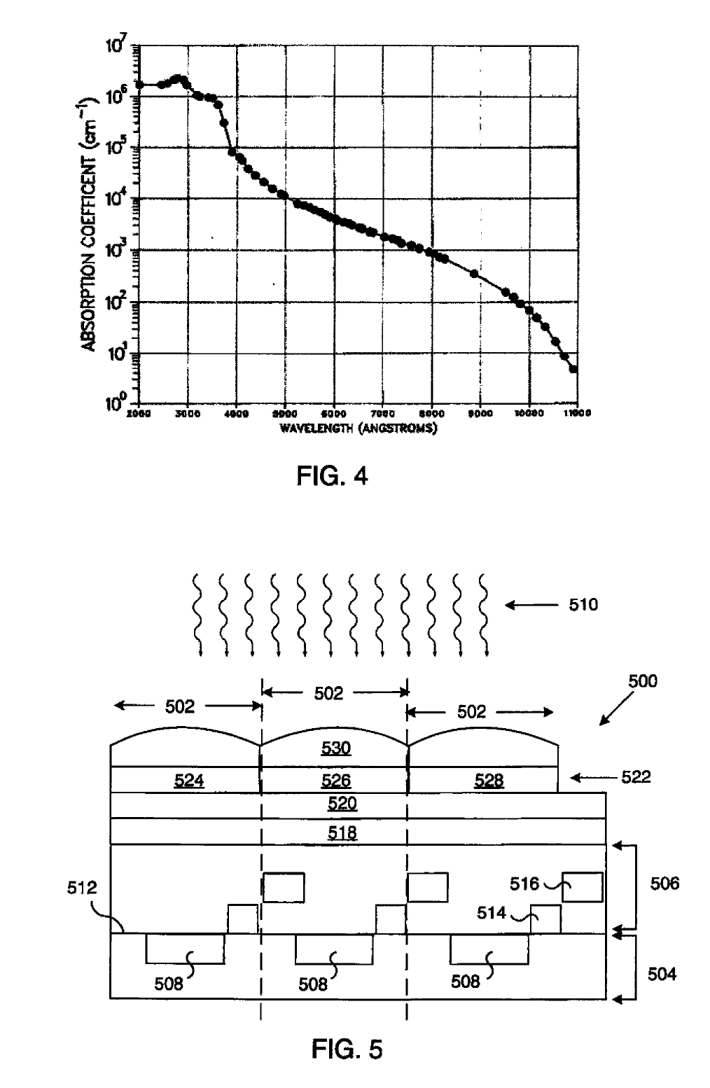

FIG. 4 is a graph depicting the silicon absorption coefficient for different wavelengths of light. As can been seen, UV light has a high absorption coefficient in silicon. Thus, a thin silicon layer will absorb most or all of the UV light generated during CFA deposition. In other embodiments in accordance with the invention, the one or more UV light filter layers can be implemented with an ONONO dichroic stack (O stands for oxide, N stands for nitride), a dyed organic or inorganic polymer layer, a UV absorbing material, or a UV absorbing material contained within a second material. One example of a second material is a glass. The UV absorbing material can include, but is not limited to, a dye, an organic or inorganic pigment, and an evaporated pigment.

Referring again to FIG. 3, a color filter array (CFA) is formed on the UV light filter layer (block 306). The CFA can include any pattern of color filter elements for any combination of colors. As discussed earlier, one commonly used type of CFA pattern is the Bayer pattern, disclosed in U.S. Pat. No. 3,971,065, entitled “Color Imaging Array,” which is incorporated by reference herein.

And finally, as shown in block 308, the microlenses are formed on the CFA. The microlenses are typically formed in an array that corresponds to the pixel array. The microlens array is commonly used to increase the light collection efficiency of an image sensor.

As discussed earlier, an image sensor can be fabricated as front-illuminated image sensor or a back-illuminated image sensor in embodiments in accordance with the invention. The “frontside” of a sensor layer is conventionally known as the side of the sensor layer that is adjacent to a circuit layer, while the “backside” is the side of the sensor layer that opposes the frontside. FIG. 5 is a cross section view of a front-illuminated image sensor fabricated pursuant to the method shown in FIG. 3 in an embodiment in accordance with the invention. Image sensor 500 includes pixels 502 formed within sensor layer 504 and circuit layer 506.

Photosensitive sites 508 are formed in sensor layer 504. Sensor layer 504 is formed with a silicon material in an embodiment in accordance with the invention. Circuit layer 506 is formed over sensor layer 504. A front-illuminated image sensor is fabricated such that light 510 from a subject scene is incident on a frontside 512 of sensor layer 504.

Circuit layer 506 includes conductive interconnects 514, 516, such as gates and connectors, formed in a dielectric material in an embodiment in accordance with the invention. Circuit layer 506 is electrically connected to sensor layer 504 through some of the conductive interconnects 514, 516. Interconnects 514, 516 in circuit layer 506 are typically associated with various metallization levels.

Insulating layer 518 is formed on circuit layer 506. Insulating layer 518 can be formed with a silicon oxide or silicon dioxide material in an embodiment in accordance with the invention. One or more UV filter layers 520 are formed on insulating layer 518. UV filter layer 520 absorbs or reflects UV light and transmits visible light in embodiments in accordance with the invention. UV filter layer 520 is implemented with any known UV filter material. By way of example only, UV filter layer 520 is formed with a thin silicon layer deposited on top of insulating layer 518, an unetched thin silicon layer if a backside illuminated image sensor is built on a Silicon-On-Insulator (SOI) wafer, an ONONO dichroic stack, or an organic or inorganic dyed polymer in exemplary embodiments in accordance with the invention.

CFA 522 is formed on UV filter layer 520. CFA 522 includes a number of color filter elements 524, 526, 528. As discussed earlier, color filter elements 524, 526, 528 provide each pixel with a color photoresponse that exhibits a predominant sensitivity to one of two or more designated portions of the visible spectrum. The designated portions may be, for example, red, green, and blue, or cyan, magenta, and yellow. And finally, microlenses 530 are formed on CFA 522.

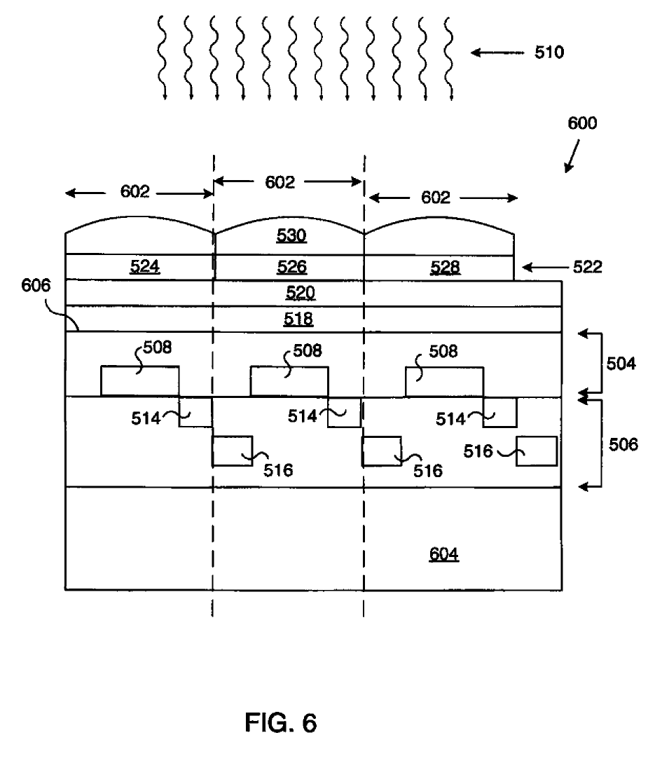

Referring now to FIG. 6, there is shown a cross section view of a back-illuminated image sensor fabricated pursuant to the method shown in FIG. 3 in an embodiment in accordance with the invention. Image sensor 600 includes pixels 602 formed within sensor layer 504 and circuit layer 506. Sensor layer 504, circuit layer 506, photodetectors 508, conductive interconnects 514, 516, insulating layer 518, UV filter layer 520, CFA 522, and microlens 530 are implemented as those shown and described in conjunction with FIG. 5.

Circuit layer 506 is disposed between sensor layer 504 and handle or support wafer 604. This allows light 510 to strike the backside 606 of sensor layer 504, where it is detected by photodetectors 508. One advantage to a back-illuminated image sensor is the detection of light 510 by photodetectors 508 is not impacted by the conductive interconnects and other features of circuit layer 506.

The invention has been described with reference to specific embodiments of the invention. However, it will be appreciated that a person of ordinary skill in the art can effect variations and modifications without departing from the scope of the invention. For example, an image sensor can include additional, fewer, or different layers or components than the ones shown in FIGS. 5 and 6. Additionally, an image sensor having a shared architecture can be used in other embodiments in accordance with the invention. One example of a shared architecture is disclosed in U.S. Pat. No. 6,107,655. And finally, the present invention can be utilized with different type of image sensors, such as, for example, Charge Coupled Device (CCD) image sensors.

Even though specific embodiments of the invention have been described herein, it should be noted that the application is not limited to these embodiments. In particular, any features described with respect to one embodiment may also be used in other embodiments, where compatible. And the features of the different embodiments may be exchanged, where compatible.

### PARTS LIST

100 image capture device
102 light
104 imaging stage
106 image sensor
108 processor
110 memory
112 display
114 other input/output (I/O) elements
200 pixel
202 imaging area
204 column decoder
206 row decoder
208 digital logic
210 output channel
500 image sensor
502 pixel
504 sensor layer
506 circuit layer
508 photodetector
510 light
512 frontside of sensor layer
514 conductive interconnect
516 conductive interconnect
518 insulating layer
520 UV filter layer
522 color filter array (CFA)
524 color filter element
526 color filter element
528 color filter element
530 microlens
600 image sensor
602 pixel
604 support wafer
606 backside of sensor layer

1. An image sensor, comprising:
at least one ultraviolet light filter layer disposed between a color filter array and an insulating layer, wherein the at least one ultraviolet light filter layer blocks UV light while transmitting visible light.

2. The image sensor of claim 1, wherein the ultraviolet light filter layer comprises a layer of silicon.

3. The image sensor of claim 1, wherein the ultraviolet light filter layer comprises a UV absorbing material.

4. The image sensor of claim 3, wherein the UV absorbing material is included in another material.

5. The image sensor of claim 3, wherein the UV absorbing material comprises an evaporated pigment.

6. The image sensor of claim 3, wherein the UV absorbing material comprises a dye.

7. The image sensor of claim 6, wherein the dye comprises one of an organic pigment and an inorganic pigment.

8. The image sensor of claim 1, wherein the image sensor comprises one of a front-illuminated image sensor and a back-illuminated image sensor.

9. A back-illuminated image sensor, comprising:
a sensor layer disposed between an insulating layer and a circuit layer electrically connected to the sensor layer, wherein a frontside of the sensor layer is adjacent to the circuit layer and a backside of the sensor layer is adjacent to the insulating layer;
one or more ultraviolet light filter layers overlying the insulating layer, wherein the at least one ultraviolet light filter layer blocks UV light while transmitting visible light; and
a color filter array formed over the one or more ultraviolet light filter layers.

10. The back-illuminated image sensor of claim 9, wherein the ultraviolet light filter layer comprises a layer of silicon.

11. The back-illuminated image sensor of claim 9, wherein the ultraviolet light filter layer comprises a UV absorbing material.

12. The image sensor of claim 11, wherein the UV absorbing material is included in another material.

13. The image sensor of claim 11, wherein the UV absorbing material comprises an evaporated pigment.

14. The back-illuminated image sensor of claim 11, wherein the UV absorbing material comprises a dye.

15. The back-illuminated image sensor of claim 14, wherein the dye comprises one of an organic pigment and an inorganic pigment.

16. A method for fabricating an image sensor having an imaging area that includes a plurality of pixels, the method comprising:
forming an insulating layer over the imaging area;
forming one or more ultraviolet light filter layers over the insulating layer, wherein the at least one ultraviolet light filter layer blocks UV light while transmitting visible light; and
forming a color filter array over the one or more ultraviolet light filter layers.

17. The method of claim 16, wherein forming one or more ultraviolet light filter layers over the insulating layer comprises forming a layer of silicon over the insulating layer.

18. The method of claim 16, wherein forming one or more ultraviolet light filter layers over the insulating layer comprises forming a UV absorbing material over the insulating layer.

19. The method of claim 18, wherein the UV absorbing material comprises a dye.

20. The method of claim 19, wherein the dye comprises one of an organic pigment and an inorganic pigment.
